(19) United States
(12) Patent Application Publication
(10) Pub. No.: US 2016/0218204 A1
(43) Pub. Date: Jul. 28, 2016

(54) Enhancement Mode High Electron Mobility Transistor and Manufacturing Method Thereof

(71) Applicant: Gpower Semiconductor, Inc., Suzhou (CN)

(72) Inventor: Yi Pei, Suzhou (CN)

(21) Appl. No.: 15/004,932

(22) Filed: Jan. 23, 2016

(30) Foreign Application Priority Data
Jan. 27, 2015 (CN) 201510040966.2

(51) Int. Cl. H01L 29/778; H01L 29/66; H01L 29/06; H01L 29/423; H01L 29/20; H01L 29/205

(52) U.S. Cl. CPC H01L 29/7787; H01L 29/2003; H01L 29/205; H01L 29/0688; H01L 29/42368; H01L 29/66462

(57) ABSTRACT

An enhancement mode high electron mobility transistor according to an embodiment of the present invention includes: a substrate; a channel layer, prepared above the substrate; a barrier layer, prepared above the channel layer; the barrier layer and the channel layer forming a heterojunction structure, and two dimensional electron gas being formed at an interface between the barrier layer and the channel layer; a groove, prepared inside the barrier layer; a semiconductor epitaxial layer, prepared above the groove by secondary growth; an in-situ dielectric layer, prepared above the semiconductor epitaxial layer; a gate electrode, prepared above the in-situ dielectric layer; a source electrode, prepared above the barrier layer; and a drain electrode, prepared above the barrier layer.

### CROSS-REFERENCE TO RELATED APPLICATION

This application claims priority from Chinese Patent Application Serial No. 201510040966.2, filed on Jan. 27, 2015, the entire contents of which are incorporated herein by reference for all purposes.

### FIELD OF THE INVENTION

The present invention is related to semiconductor technology, particularly to an enhancement mode high electron mobility transistor and manufacturing method thereof.

### BACKGROUND OF THE INVENTION

The third generation of wide band gap semiconductor materials, represented by GaN, has many excellent properties such as wide band gap, high critical breakdown electric field intensity, high electron saturation drift velocity, high thermal conductivity and high concentration of two dimensional electron gas at a heterogeneous interface, so it is more suitable than Si material for being used in the production of power electronic devices having high power, high voltage and high switching speed. Compared with traditional silicon devices, the GaN devices can carry a higher power density and have higher energy conversion efficiency, therefore the volume and weight of a whole system is reduced, and the cost of the system is also reduced.

Nowadays, most studies in the art are about depletion mode GaN HEMT (High Electron Mobility Transistor) devices. The reason lies in that a large amount of charges are generated by spontaneous polarization and piezoelectric polarization at the interface of AlGaN/GaN heterojunction, therefore high concentration of 2DEG (Two Dimensional Electron Gas) is formed therein. The high concentration of 2DEG makes the threshold voltage value of the GaN HEMT devices negative. In an AlGaN/GaN HEMT, the threshold voltage value may be about −4V. In this case, only when a high enough negative bias voltage is applied to the gate electrode of the GaN HEMT, the 2DEG at the interface of AlGaN/GaN heterojunction can be in a depletion state and the device can be turned off. However, when the traditional depletion mode GaN HEMT device is used in an application of radio frequency microwave and high voltage, the circuit structure has to be very complicated due to having a negative threshold voltage. Especially in an application of high voltage switches, the failure security requires the device being in off state when none voltage is applied to the gate electrode. Thus, it is necessary to design an enhancement mode GaN HEMT device which has a positive threshold voltage and can be turned on/off by applying a positive bias voltage to the gate electrode, and obsolete the circuit structure having a negative threshold voltage to simplify the circuit structure and the designing complexity and reduce the manufacturing cost.

Originally, the enhancement mode GaN HEMT is manufactured by imitating the manufacturing process of GaAs. By forming a groove under the gate electrode, the thickness of a barrier layer can be reduced so the value of the threshold voltage can be controlled. In the prior art, dry etching process is mostly used by domestic and foreign researchers and manufactures to form the groove under the gate electrode. However the threshold voltage value of the GaN HEMT prepared by this process is low, which is about 0-1V, meanwhile the gate leakage current is high and the dynamic range of gate voltage is small.

GaN MISFET (Metal Insulator Semiconductor Field Transistors) has a large dynamic range of gate voltage and low gate leakage current. However, due to the lack of a suitable gate dielectric layer, the interface state density between the gate dielectric layer and a barrier layer of the GaN MISFET is high. Charging and discharging processes at the interface may cause threshold voltage drift, and high frequency performance of the device may be degraded. For example, in a traditional manufacturing method, a dielectric layer is normally prepared after groove etching. When the dielectric layer is prepared, the surface of the barrier layer is exposed in the air, so an oxide layer and dangling bonds are formed on the barrier layer. Thus, after the preparation of the dielectric layer, there will be high density of interface state defects formed at the interface between the dielectric layer and the barrier layer, and the interface state defects will cause hysteresis effect and DC/AC dispersion effect.

By introducing in-situ SiN preparing technology to manufacture GaN HEMT, the interface state density can be reduced and the hysteresis effect can be restrained. However, due to the existence of GaN polarization charges, the enhancement mode GaN HEMT is still hard to be produced. One manufacturing method is preparing a groove by a dry etching process and then depositing a dielectric layer above the groove directly. But the dry etching process may lead to a lot of damages and defects on an AlGaN barrier layer, and these damages and defects may lead to high interface state density. As a result, the gate leakage current may be increased and current collapse and dynamic parameter degradation may be caused, all of which may severely affect the performance of the device. Therefore, it is highly required to put forward an enhancement mode GaN HEMT with low interface state density and manufacturing method thereof.

### SUMMARY OF THE INVENTION

The technical scheme of the present invention is to overcome the problems in the prior art mentioned above. The purpose of the present invention is to provide an enhancement mode GaN HEMT and manufacturing method thereof, which can achieve an enhancement mode device and solve the problem of high interface state density in the prior art at the same time.

According to an embodiment of the present invention, an enhancement mode high electron mobility transistor includes:

a substrate;

a channel layer, prepared above the substrate;

a barrier layer, prepared above the channel layer; the barrier layer and the channel layer forming a heterojunction structure, and two dimensional electron gas being generated at the interface between the barrier layer and the channel layer;

a groove, prepared inside the barrier layer;

a semiconductor epitaxial layer, prepared above the groove by secondary growth;

an in-situ dielectric layer, prepared above the semiconductor epitaxial layer;

a gate electrode, prepared above the in-situ dielectric layer;

a source electrode, prepared above the barrier layer; and

a drain electrode, prepared above the barrier layer.

According to an embodiment of the present invention, a manufacturing method of an enhancement mode high electron mobility transistor includes:

depositing a channel layer and a barrier layer above a substrate sequentially;

preparing a groove inside the barrier layer;

preparing a semiconductor epitaxial layer above the groove by secondary growth, and preparing an in-situ dielectric layer above the semiconductor epitaxial layer; and

preparing a gate electrode above the in-situ dielectric layer, and preparing a source electrode and a drain electrode above the barrier layer.

According to an enhancement mode HEMT provided by an embodiment of the present invention, a semiconductor epitaxial layer prepared by secondary growth and an in-situ dielectric layer are formed between a groove and a gate electrode, so damages and defects caused by groove etching are decreased, the interface state density between the groove and the semiconductor epitaxial layer and the interface state density between the in-situ dielectric layer and the semiconductor epitaxial layer are decreased. Thus, the gate leakage current can be reduced, the performance of the gate electrode can be improved, the breakdown voltage and the power performance of the device can be enhanced, and the current collapse effect can be restrained.

### BRIEF DESCRIPTION OF THE DRAWINGS

In order to describe the technical scheme of the present invention more clearly, the drawings of following embodiments are briefly introduced as follows. Obviously, the drawings introduced hereinafter can only illustrate a part of embodiments of the present invention but not all the embodiments. Those skilled in the art may acquire other drawings based on the following drawings without any creative work.

FIG. 1 illustrates a structure of an enhancement mode high electron mobility transistor according to Embodiment I of the present invention.

FIG. 2A, FIG. 2B1, FIG. 2B2, FIG. 2C1 and FIG. 2C2 illustrate the structures corresponding to the steps of a manufacturing method of an enhancement mode high electron mobility transistor according to Embodiment I.

FIG. 3 illustrates a structure of an enhancement mode high electron mobility transistor according to Embodiment II of the present invention.

FIG. 4A, FIG. 4B1, FIG. 4B2, FIG. 4C, FIG. 4D1, FIG. 4D2 and FIG. 4D3 illustrate the structures corresponding to the steps of a manufacturing method of an enhancement mode high electron mobility transistor according to Embodiment II.

FIG. 5 illustrates a structure of an enhancement mode high electron mobility transistor according to Embodiment III of the present invention.

FIG. 6A, FIG. 6B1, FIG. 6B2, FIG. 6C1, FIG. 6C2 and FIG. 6D illustrate the structures corresponding to the steps of a manufacturing method of an enhancement mode high electron mobility transistor according to Embodiment III.

FIG. 7 illustrates a structure of an enhancement mode high electron mobility transistor according to Embodiment IV of the present invention.

FIG. 8 illustrates a structure of an enhancement mode high electron mobility transistor according to Embodiment V of the present invention.

### DETAILED DESCRIPTION OF THE INVENTION

In order to clarify the purpose, the technical scheme and the advantages of the present invention, the technical scheme will be described in detail hereinafter with drawings provided by specific embodiments of the present invention. Obviously, the embodiments described hereinafter are only a part, but not all embodiments of the present invention. Any other embodiments acquired by those skilled in the art without any creative work are all considered to be within the protection scope of the present invention.

### Embodiment I

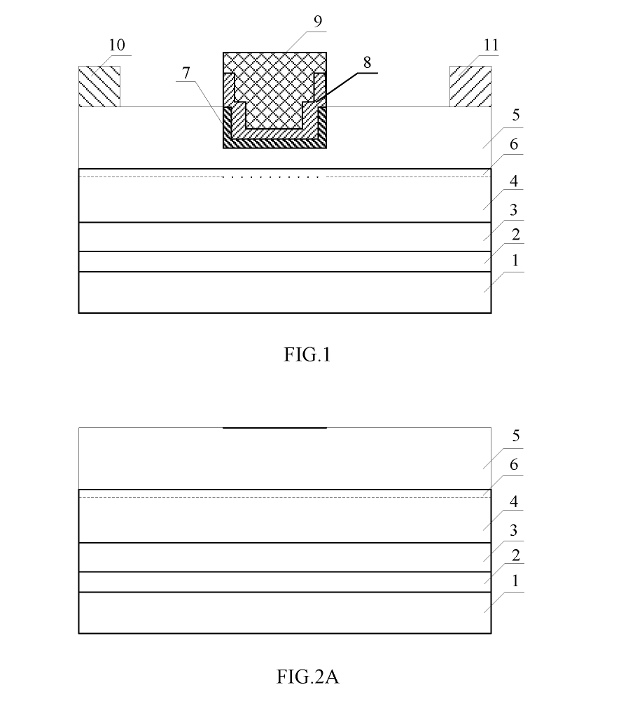

FIG. 1 illustrates a structure of an enhancement mode high electron mobility transistor according to Embodiment I of the present invention. As shown in FIG. 1, the enhancement mode high electron mobility transistor includes: a substrate 1, a nucleation layer 2, a buffer layer 3, a channel layer 4, a barrier layer 5, a groove, a semiconductor epitaxial layer 7, an in-situ dielectric layer 8, a gate electrode 9, a source electrode 10 and a drain electrode 11.

According to an embodiment of the present invention, the substrate 1 may be made of Si, GaN, SiC or sapphire.

The nucleation layer 2 is prepared above the substrate 1.

According to an embodiment of the present invention, the nucleation layer 2 may be made of AlN, GaN or other III-V compounds.

The buffer layer 3 is prepared above the nucleation layer 2.

According to an embodiment of the present invention, the buffer layer 3 may be made of AlGaN or other III-V compounds.

The channel layer 4 is prepared above the buffer layer 3.

According to an embodiment of the present invention, the channel layer 4 may be made of GaN or other III-V compounds.

The barrier layer 5 is prepared above the channel layer 4. A heterojunction structure is formed between the barrier layer 5 and the channel layer 4, and 2DEG 6 is formed at the interface between the barrier layer 5 and the channel layer 4.

According to an embodiment of the present invention, the barrier layer 5 may be made of AlGaN or other III-V compounds.

The groove is prepared inside the barrier layer 5, and the depth of the groove is less than the thickness of the barrier layer 5.

According to an embodiment of the present invention, the groove may be rectangle shaped, U shaped, V shaped or trapezoid shaped.

The semiconductor epitaxial layer 7 is prepared above the groove by secondary growth.

According to an embodiment of the present invention, the semiconductor epitaxial layer 7 may be made of AlGaN, N-type GaN, P-type GaN or other III-V compounds.

The in-situ dielectric layer 8 is prepared above the semiconductor epitaxial layer 7.

According to an embodiment of the present invention, the in-situ dielectric layer 8 may be made of SiN or other nitride.

The gate electrode 9 is prepared above the in-situ dielectric layer 8.

Due to the existence of the groove, the gate electrode 9 is close to the 2DEG 6, so the gate electrode 9 can control the 2DEG 6 more easily.

According to an embodiment of the present invention, the gate electrode 9 may be prepared by laminating one or more gate metal layers.

The source electrode 10 is prepared above the barrier layer 5. An ohmic contact is formed between the barrier layer 5 and the source electrode 10.

According to an embodiment of the present invention, the source electrode 10 may be prepared by laminating one or more source metal layers. The source metal layers may be made of one or any combination of titanium, aluminum, nickel and gold.

The drain electrode 11 is prepared above the barrier layer 5. An ohmic contact is formed between the barrier layer 5 and the drain electrode 11.

According to an embodiment of the present invention, both of the source electrode 10 and the drain electrode 11 may be prepared by laminating one or more metal layers. The metal layers may be made of one or any combination of titanium, aluminum, nickel and gold.

Due to the piezoelectric polarization effect and the spontaneous polarization effect between the barrier layer 5 and the channel layer 4, 2DEG 6 is formed at the interface between the barrier layer 5 and the channel layer 4. Since the barrier layer has a smaller thickness under the groove, the piezoelectric polarization effect and the spontaneous polarization effect at the part is not enough to generate a high concentration of 2DEG 6, thus the 2DEG channel therein is depleted. Thus, a normally-off type transistor is acquired, which is namely an enhancement mode device. Meanwhile, since the gate electrode 9 in the groove is close to the channel, the gate electrode 9 can control the channel strongly. Polarization charges may be introduced into the semiconductor epitaxial layer 7 in the groove, thus the 2DEG 6 may be further depleted and the threshold voltage may be increased. After the semiconductor epitaxial layer 7 is prepared, the in-situ dielectric layer 8 may be in-situ grown by the same preparing process as the semiconductor epitaxial layer 7. In this case, the in-situ dielectric layer 8 can achieve an excellent crystal quality, and the interface state density between the semiconductor epitaxial layer 7 and the in-situ dielectric layer 8 is low. Therefore, the threshold voltage drift can be significantly restrained, the gate leakage current can be reduced and the dynamic performance of the device can be improved.

According to an embodiment of the present invention, a manufacturing method of the enhancement mode high electron mobility transistor includes:

Step 201, a nucleation layer 2, a buffer layer 3, a channel layer 4 and a barrier layer 5 are deposited above a substrate 1 sequentially.

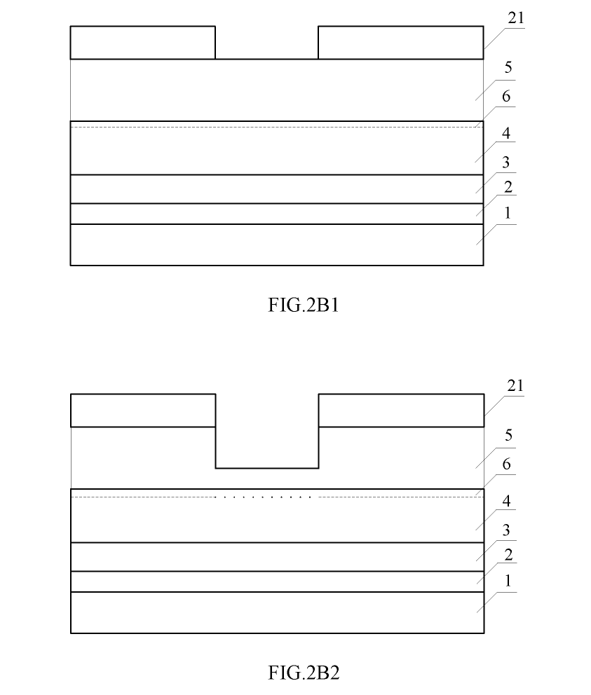

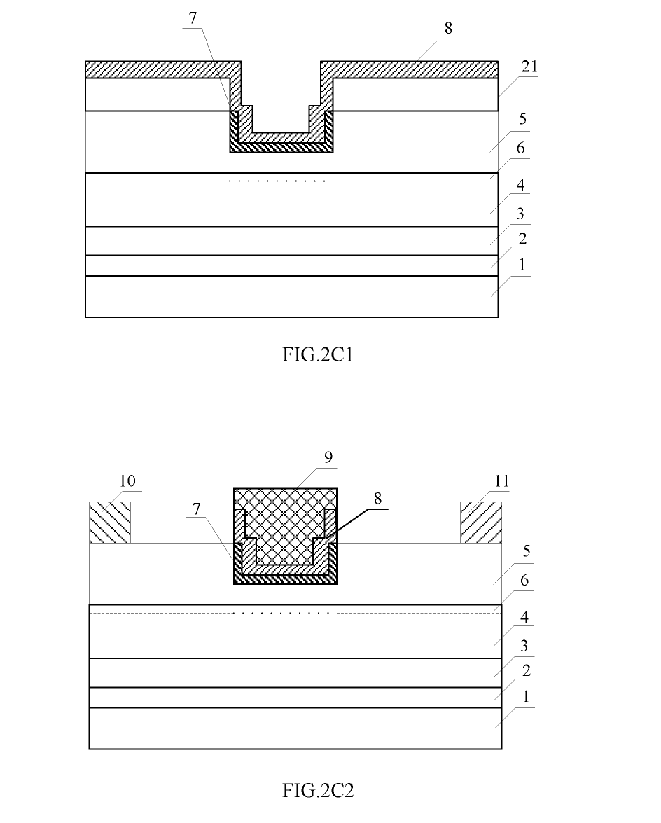

As shown in FIG. 2A, in a growth chamber, the nucleation layer 2, the buffer layer 3, the channel layer 4 and the barrier layer 5 may be prepared above the substrate 1 sequentially through metal organic chemical vapor deposition processes.

Step 202, a groove is prepared inside the barrier layer 5.

Preferably, Step 202 may include following steps:

Step 212, a mask window is formed above the barrier layer 5.

As shown in FIG. 2B1, the wafer is placed outside the growth chamber, and the mask window is formed above the barrier layer 5 through a photolithography process. A mask layer made of SiN or other nitride formed in Step 212 is referenced as 21.

Step 222, a groove is formed by etching the barrier layer 5.

As shown in FIG. 2B2, a dry etching or wet etching process may be applied to etch the barrier layer 5 to form the groove.

Step 203, the wafer is placed inside the growth chamber, and a semiconductor epitaxial layer 7 prepared by secondary growth, an in-situ dielectric layer 8, a gate electrode 9, a source electrode 10 and a drain electrode 11 are formed above the groove sequentially.

Preferably, Step 203 may include following steps:

Step 213, the wafer surface is cleaned.

In this step, the wafer surface is cleaned to remove the gas adsorbed on the wafer surface.

Step 223, the semiconductor epitaxial layer 7 is prepared above the groove by secondary growth.

As shown in FIG. 2C1, in the growth chamber, a metal organic chemical vapor deposition process may be applied to form the semiconductor epitaxial layer 7 above the groove by secondary growth.

Step 233, the in-situ dielectric layer 8 is prepared above the semiconductor epitaxial layer 7.

As shown in FIG. 2C1, the wafer is not exposed in the air but placed in the growth chamber, and a metal organic chemical vapor deposition process may be applied to prepare the in-situ dielectric layer 8 above the semiconductor epitaxial layer 7.

Step 243, the gate electrode 9 is prepared above the in-situ dielectric layer 8, and the source electrode 10 and the drain electrode 11 are prepared above the barrier layer 5.

In this step, the preparing process of the source electrode 10 and the drain electrode 11 may include a dry etching process to remove the mask layer 21. The device finally acquired is shown in FIG. 2C2.

According to an embodiment of the present invention, by preparing the semiconductor epitaxial layer 7 between the groove and the gate electrode 9 through secondary growth, the damages and defects caused by groove etching are reduced, and the interface state density between the semiconductor epitaxial layer 7 and the dielectric layer 8 is decreased. Therefore, the threshold voltage drift can be significantly restrained, the gate leakage current can be reduced and the dynamic performance of the device can be improved.

### Embodiment II

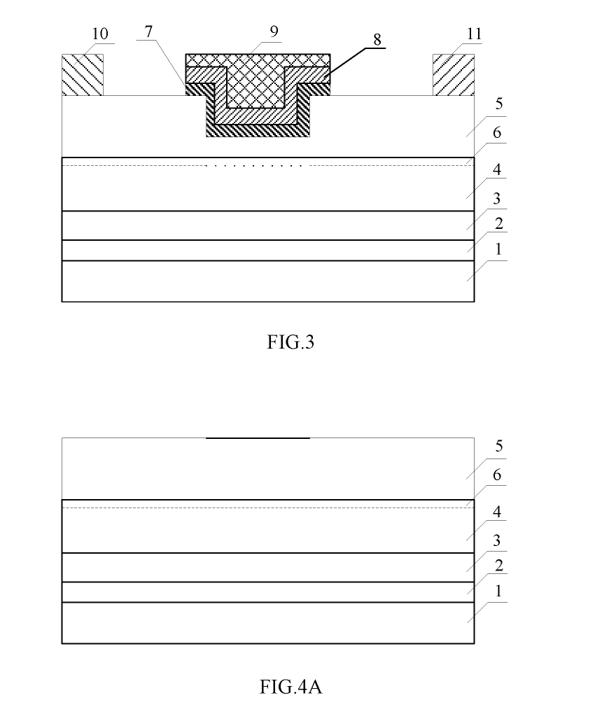

FIG. 3 illustrates a structure of an enhancement mode high electron mobility transistor according to Embodiment II of the present invention. As shown in FIG. 3, different from the structure in Embodiment I, a semiconductor epitaxial layer 7 prepared by secondary growth extends towards the source electrode 10 and the drain electrode 11 to form a junction termination structure. When the Al component of the semiconductor epitaxial layer 7 is less than the Al component of the barrier layer 5, 2DEG 6 in the junction termination structure may be depleted to a certain extent, so the electric field peak at the edge of a gate electrode 9 may be weaken, and the breakdown voltage of the device may be increased.

A manufacturing method of the enhancement mode high electron mobility transistor according to embodiment II of the present invention may include following steps:

Step 401, a nucleation layer 2, a buffer layer 3, a channel layer 4 and a barrier layer 5 are deposited above a substrate 1 sequentially.

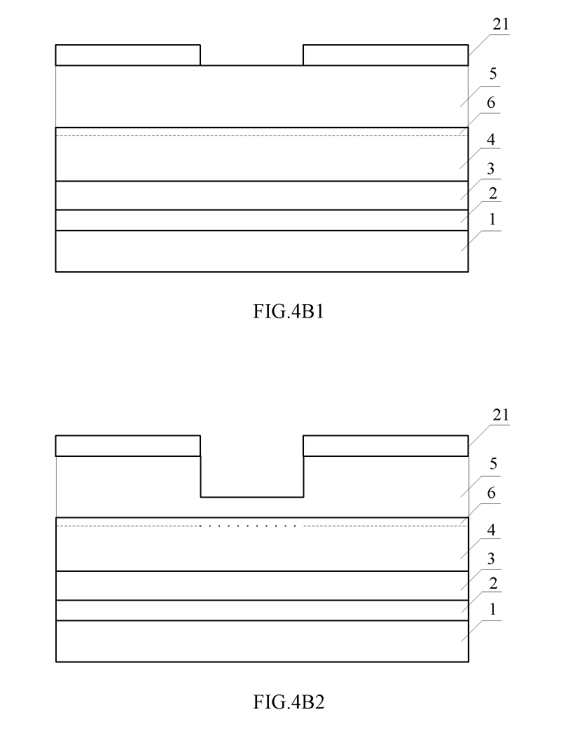

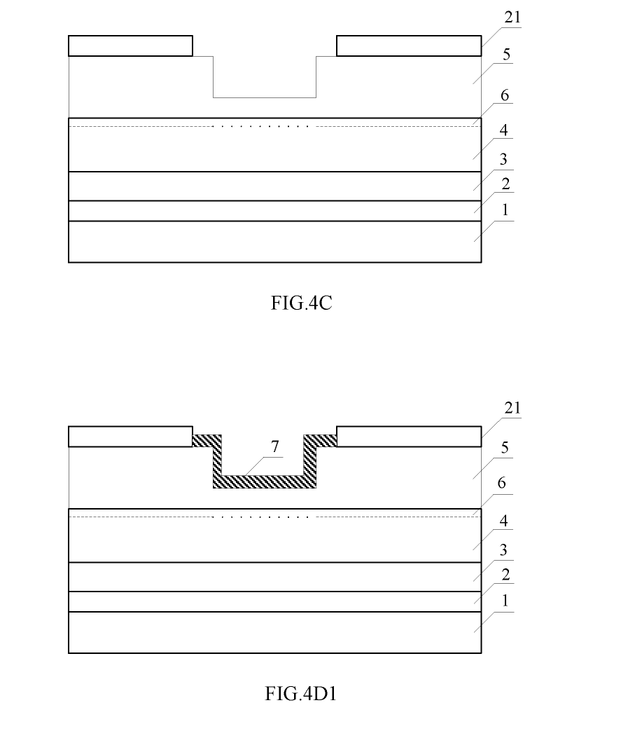

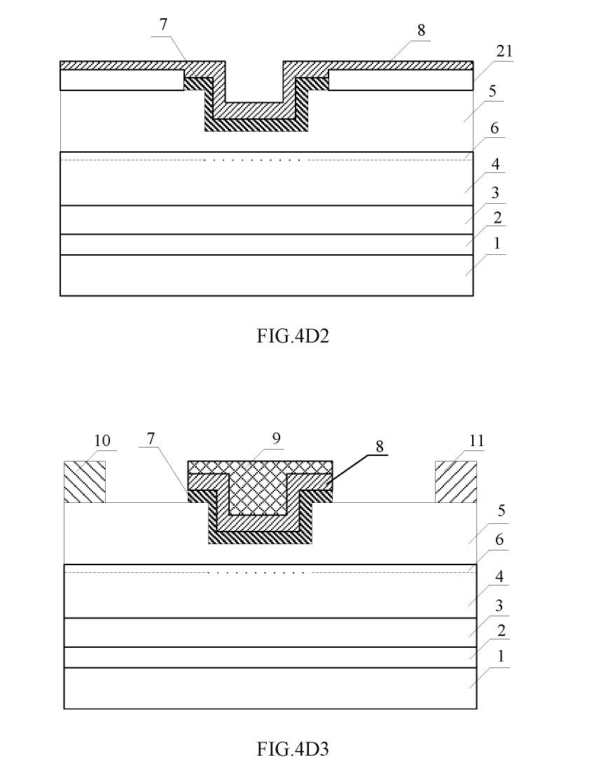

As shown in FIG. 4A, in a growth chamber, the nucleation layer 2, the buffer layer 3, the channel layer 4 and the barrier layer 5 may be prepared above the substrate 1 sequentially through metal organic chemical vapor deposition processes.

Step 402, a groove is prepared inside the barrier layer 5.

Preferably, Step 402 may include following steps:

Step 412, a mask window is formed above the barrier layer 5.

As shown in FIG. 4B1, the wafer is placed outside the growth chamber, and the mask window is formed above the barrier layer 5 through a photolithography process. A mask layer made of SiN or other nitride formed in Step 412 is shown as 21.

Step 422, a groove is formed by etching the barrier layer 5.

As shown in FIG. 4B2, a dry etching or wet etching process may be applied to etch the barrier layer 5 to form the groove.

Step 403, as shown in FIG. 4C, a platform is formed by a mask layer 21 through a photolithography process.

Step 404, a semiconductor epitaxial layer 7 prepared by secondary growth, an in-situ dielectric layer 8, a gate electrode 9, a source electrode 10 and a drain electrode 11 are formed above the groove sequentially.

Preferably, Step 404 includes following steps:

Step 414, the wafer surface is cleaned.

In this step, the wafer surface is cleaned to remove the gas adsorbed on the wafer surface.

Step 424, the semiconductor epitaxial layer 7 is prepared by secondary growth above the groove.

As shown in FIG. 4D1, in the growth chamber, a metal organic chemical vapor deposition process may be applied to prepare the semiconductor epitaxial layer 7 above the groove by secondary growth.

Step 434, the in-situ dielectric layer 8 is prepared above the semiconductor epitaxial layer 7.

As shown in FIG. 4D2, the wafer is not exposed in the air but placed in the growth chamber, and a metal organic chemical vapor deposition process may be applied to prepare the in-situ dielectric layer 8 above the semiconductor epitaxial layer 7.

Step 444, the gate electrode 9 is prepared above the in-situ dielectric layer 8, and the source electrode 10 and the drain electrode 11 are prepared above the barrier layer 5.

In this step, the preparing process of the source electrode 10 and the drain electrode 11 may include a dry etching process to remove the mask layer 21. The device finally acquired is shown in FIG. 4D3.

Compared with the structure in Embodiment I, the semiconductor epitaxial layer 7 prepared by secondary growth extends towards the drain electrode 11 according to Embodiment II. Except for having the advantages of low interface state density and high dynamic performance, when the semiconductor epitaxial layer 7 is made of n-type GaN, p-type GaN or p-type AlGaN, or the Al component in the semiconductor epitaxial layer 7 is less than the Al component in the barrier layer 5, the 2DEG 6 under the junction termination structure can be depleted to a certain extent, so the electric field peak at the edge of the gate electrode 9 can be weaken, and the breakdown voltage of the device can be increased.

### Embodiment III

FIG. 5 illustrates a structure of an enhancement mode high electron mobility transistor according to Embodiment III of the present invention. As shown in FIG. 5, different from the structure in Embodiment II, the enhancement mode high electron mobility transistor according to Embodiment III further includes: an in-situ mask layer 12, prepared above a barrier layer 5; and an in-situ dielectric layer 8 is prepared above the semiconductor epitaxial layer 7 and the in-situ mask layer 12.

According to an embodiment of the present invention, after preparing the barrier layer 5, the wafer is not taken out from the growth chamber and the in-situ mask layer 12 is in-situ grown above the barrier layer 5 by the same preparing process as the barrier layer 5. In this case, the in-situ mask layer 12 can achieve an excellent crystal quality, and the interface state density between the in-situ mask layer 12 and the barrier layer 5 can be decreased. In an embodiment, the in-situ mask layer 12 may be made of SiN or other nitride.

According to the embodiment of the present invention, a manufacturing method of the enhancement mode high electron mobility transistor includes following steps:

Step 601, a nucleation layer 2, a buffer layer 3, a channel layer 4, a barrier layer 5 and an in-situ mask layer 12 are deposited above a substrate 1 sequentially.

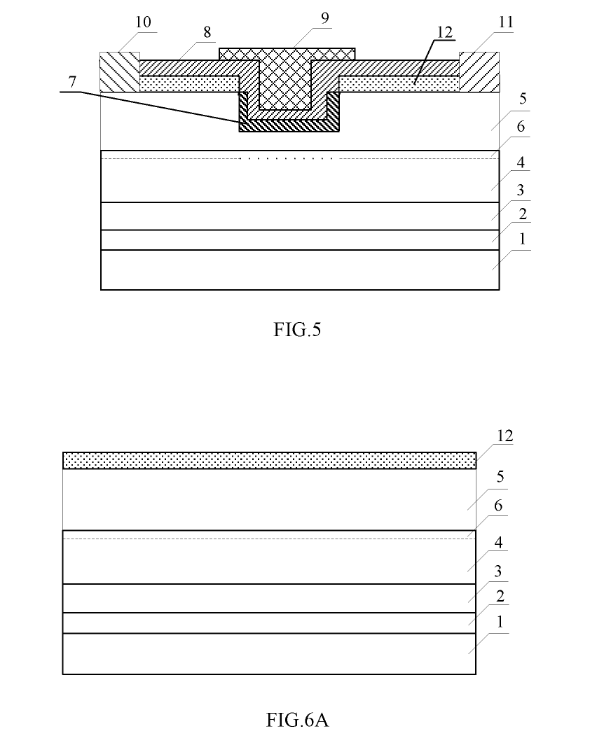

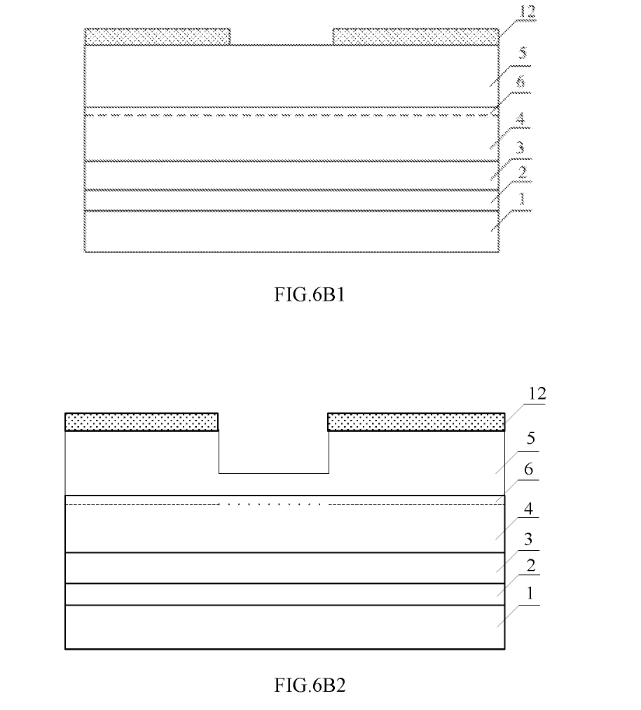

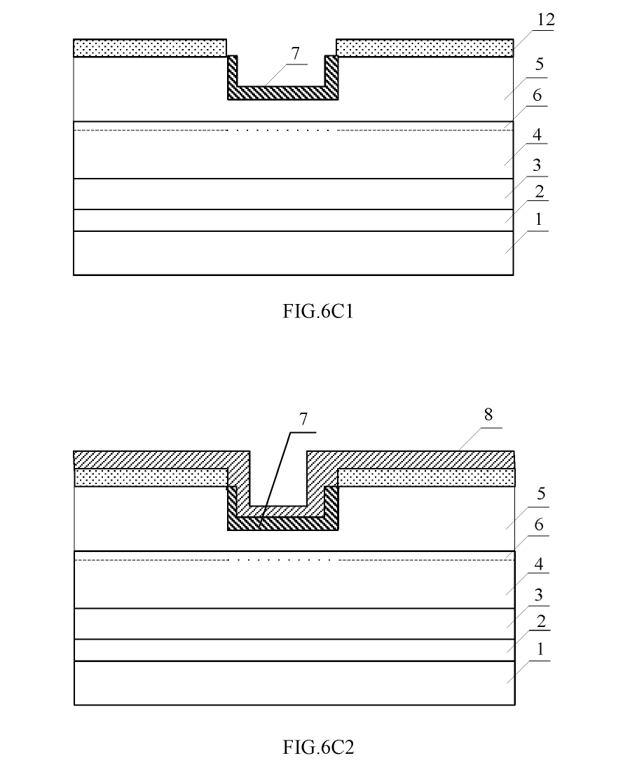

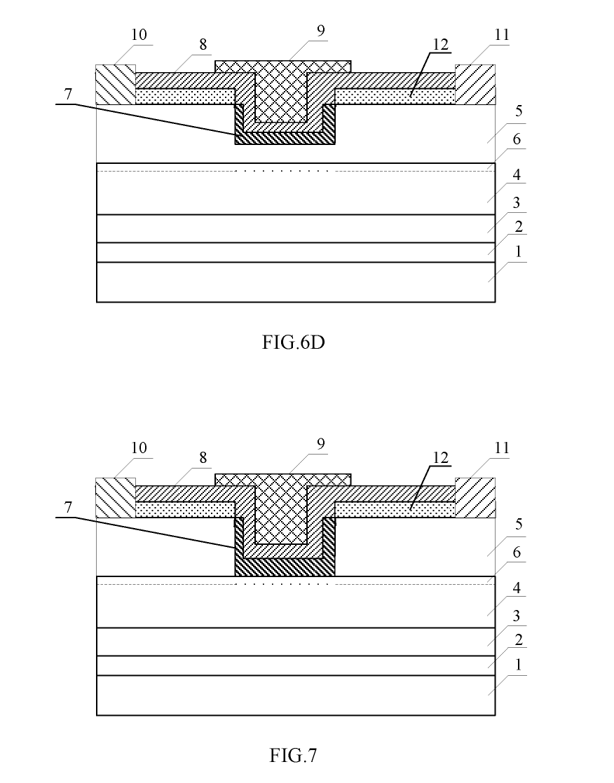

As shown in FIG. 6A, in a growth chamber, the nucleation layer 2, the buffer layer 3, the channel layer 4, the barrier layer 5 and the in-situ mask layer 12 may be prepared above the substrate 1 sequentially through metal organic chemical vapor deposition processes.

Step 602, a groove is prepared inside the barrier layer 5.

Preferably, Step 602 may include following steps:

Step 612, a mask window is formed above the barrier layer 5.

As shown in FIG. 6B1, the wafer is placed outside the growth chamber, and the mask window is formed above the barrier layer 5 through a photolithography process.

Step 622, a groove is formed by etching the barrier layer 5.

As shown in FIG. 6B2, a metal organic chemical vapor deposition process may be applied to etch the barrier layer 5 to form the groove. In the metal organic chemical vapor deposition process, hydrogen gas, chlorine gas, ammonia gas or other gas may be introduced into the growth chamber to etch the barrier layer 5, the substrate temperature may be controlled within 700° C.-1200° C., and the depth of the groove may be adjusted by controlling the etching time.

Step 603, the wafer is placed inside the growth chamber, and a semiconductor epitaxial layer 7 prepared by secondary growth and an in-situ dielectric layer 8 are formed above the groove.

Preferably, Step 603 may include following steps:

Step 613, the semiconductor epitaxial layer 7 is prepared above the groove by secondary growth.

As shown in FIG. 6C1, the wafer is not exposed in the air. In the growth chamber, a metal organic chemical vapor deposition process may be applied to prepare the semiconductor epitaxial layer 7 above the groove.

Step 623, the in-situ dielectric layer 8 is prepared above the semiconductor epitaxial layer 7.

As shown in FIG. 6C2, the wafer is not exposed in the air but placed in the growth chamber, and a metal organic chemical vapor deposition process may be applied to prepare the in-situ dielectric layer 8 above the semiconductor epitaxial layer 7 and the in-situ mask layer 12.

Step 604, a gate electrode 9 is prepared above the in-situ dielectric layer 8, and a source electrode 10 and a drain electrode 11 are prepared above the barrier layer 5. The device finally acquired is shown in FIG. 6D.

Compared with the structure in Embodiment II, the in-situ mask layer 12 is introduced into the enhancement mode HEMT and the manufacturing method thereof according to Embodiment III. The wafer is not exposed in the air, so the etching interface of the barrier layer 5 cannot be oxidized. After the barrier layer 5 is etched by hydrogen gas, chlorine gas, ammonia gas or other gas in a metal organic chemical vapor deposition process, the semiconductor epitaxial layer 7 is directly grown, therefore the defects and dislocations in the growth interface can be greatly decreased. Thus, the interface state density between the in-situ dielectric layer 8 and the in-situ semiconductor layer 7 is decreased, and the interface state density between the in-situ semiconductor layer 7 and the barrier layer 5 introduced by groove etching is also decreased. Therefore, the threshold voltage drift of the device can be greatly restrained, the gate leakage current can be reduced, and the dynamic performance of the device can be improved.

### Embodiment IV

FIG. 7 illustrates a structure of an enhancement mode high electron mobility transistor according to Embodiment IV of the present invention. As shown in FIG. 7, different from the structure in Embodiment III, a groove is constructed vertically throughout a barrier layer 5, and a bottom surface of the groove below a gate electrode 9 extends to an upper surface of a channel layer 4.

Compared with the structure in Embodiment III, in a manufacturing method of the enhancement mode HEMT according to Embodiment IV, when applying a metal organic chemical vapor deposition process to etching the barrier layer 5, hydrogen etching time and temperature need to be controlled to make the bottom surface of the groove just extend to the upper surface of the channel layer 4.

Compared with the structure in Embodiment III, the enhancement mode HEMT and the manufacturing method thereof according to Embodiment IV have advantages of slow interface state density, low gate leakage current, stable threshold voltage, and excellent dynamic performance. Moreover, the bottom surface of the groove extends to the upper surface of the channel layer in the enhancement mode HEMT according to Embodiment IV, therefore the concentration of two-dimensional electron gas 6 under the gate electrode 9 is lower and the threshold voltage is higher, therefore noise turning on and the gate leakage current of the device are effectively restrained. In addition, the preparation processes according to Embodiment IV are easily to be controlled and achieved.

### Embodiment V

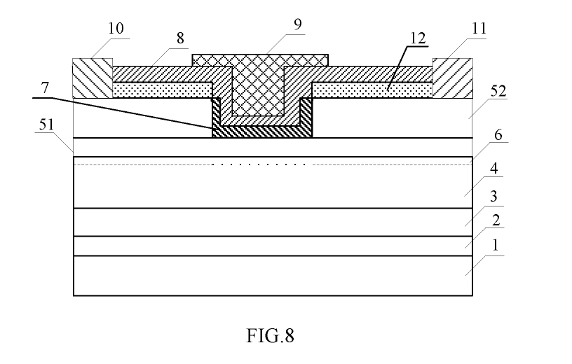

FIG. 8 illustrates a structure of an enhancement mode high electron mobility transistor according to Embodiment V of the present invention. As shown in FIG. 8, different from the structure according to Embodiment III, along the direction from a channel layer 4 to a semiconductor epitaxial layer 7, a barrier layer 5 is divided into a first barrier layer 51 and a second barrier layer 52. A bottom surface of a groove is located on the boundary between the first barrier layer 51 and the second barrier layer 52, and the component of the first barrier layer 51 is different from the component of the second barrier layer 52.

Compared with the structure in Embodiment III, in a manufacturing method of the enhancement mode HEMT according to Embodiment V, after the barrier layer 5 is etched to form the groove, the bottom surface of the groove is located on the boundary between the first barrier layer 51 and the second barrier layer 52.

Compared with the structure in Embodiment III, the enhancement mode HEMT and the manufacturing method thereof according to Embodiment V also have advantages of slow interface state density, low gate leakage current, stable threshold voltage, and excellent dynamic performance. Moreover, the thickness of the first barrier layer 51 can be adjusted to make the two dimensional gas 6 below the groove achieve varying degrees of depletion, so that the threshold voltage of the enhancement mode HEMT can be easily adjusted.

It should be understood that the embodiments described herein should be considered in a descriptive sense only and not for purposes of limitation. Descriptions of features or aspects within each embodiment should typically be considered as available for other similar features or aspects in other embodiments. While one or more embodiments of the present invention have been described with reference to the drawings, it will be understood by those of ordinary skill in the art that various changes in form and details may be made therein without departing from the spirit and scope of the present invention as defined by the following claims and their equivalents. The protection scope of the present invention is only defined by the claims.

What is claimed is:

1. An enhancement mode high electron mobility transistor, comprising:
a substrate;
a channel layer, prepared above the substrate;
a barrier layer, prepared above the channel layer; the barrier layer and the channel layer forming a heterojunction structure, and two dimensional electron gas being formed at an interface between the barrier layer and the channel layer;
a groove, prepared inside the barrier layer;
a semiconductor epitaxial layer, prepared above the groove by secondary growth;
an in-situ dielectric layer, prepared above the semiconductor epitaxial layer;
a gate electrode, prepared above the in-situ dielectric layer;
a source electrode, prepared above the barrier layer; and
a drain electrode, prepared above the barrier layer.

2. The enhancement mode high electron mobility transistor according to claim 1, wherein semiconductor epitaxial layer in-situextends towards the source electrode and the drain electrode.

3. The enhancement mode high electron mobility transistor according to claim 2, wherein both of the semiconductor epitaxial layer and the barrier layer contain Al, and the Al component of the semiconductor epitaxial layer is less than the Al component of the barrier layer.

4. The enhancement mode high electron mobility transistor according to claim 1, further comprising:
an in-situ mask layer, prepared above the barrier layer; wherein the in-situ dielectric layer is prepared above the semiconductor epitaxial layer and the in-situ mask layer.

5. The enhancement mode high electron mobility transistor according to claim 4, wherein the in-situ mask layer is made of a nitride.

6. The enhancement mode high electron mobility transistor according to claim 1, wherein the depth of the groove is equal with or less than the thickness of the barrier layer.

7. The enhancement mode high electron mobility transistor according to claim 1, wherein the barrier layer comprises a first barrier layer and a second barrier layer below the first barrier layer, and a bottom surface of the groove is located on a boundary between the first barrier layer and the second barrier layer.

8. The enhancement mode high electron mobility transistor according to claim 7, wherein the component of the first barrier layer is different from the component of the second barrier layer.

9. The enhancement mode high electron mobility transistor according to claim 1, wherein the source electrode and the barrier layer form an ohmic contact; and/or
the drain electrode and the barrier layer form an ohmic contact.

10. The enhancement mode high electron mobility transistor according to claim 1, wherein the groove is rectangle shaped, U shaped, V shaped or trapezoid shaped.

11. The enhancement mode high electron mobility transistor according to claim 1, wherein the substrate is made of one of Si, GaN, SiC and sapphire; and/or
the channel layer is made of a III-V compound; and/or
the barrier layer is made of a III-V compound; and/or
the semiconductor epitaxial layer is made of a III-V compound; and/or
the in-situ dielectric layer is made of a nitride.

12. A manufacturing method of an enhancement mode high electron mobility transistor, comprising:
depositing a channel layer and a barrier layer above a substrate sequentially;
preparing a groove inside the barrier layer;
preparing a semiconductor epitaxial layer above the groove by secondary growth, and preparing an in-situ dielectric layer above the semiconductor epitaxial layer; and
preparing a gate electrode above the in-situ dielectric layer, and preparing a source electrode and a drain electrode above the barrier layer.

13. The manufacturing method according to claim 12, wherein preparing a groove inside the barrier layer comprises:
Preparing a mask layer;
forming a mask window above the barrier layer through a photolithography process;
applying a dry etching process, a wet etching process or a metal organic chemical vapor deposition process to etch the barrier layer in the growth chamber to form the groove.

14. The manufacturing method according to claim 13, wherein the groove is formed by applying the metal organic chemical vapor deposition process to etch the barrier layer in the growth chamber, and the metal organic chemical vapor deposition process comprises:
controlling etching time and temperature to make a bottom surface of the groove just extend to the upper surface of the channel layer; or
controlling etching time and temperature to make a bottom surface of the groove be located on a boundary between a first barrier layer and a second barrier layer; wherein the barrier layer comprises the first barrier layer and the second barrier layer below the first barrier layer.

15. The manufacturing method according to claim 13, wherein the gas used in the metal organic chemical vapor deposition process is hydrogen gas, chlorine gas or ammonia gas; and/or
the substrate temperature used in the metal organic chemical vapor deposition process is controlled within 700° C.-1200° C.

16. The manufacturing method according to claim 12, wherein the preparing process of the secondary growth semiconductor epitaxial layer is the same as the preparing process of the in-situ dielectric layer.

17. The manufacturing method according to claim 16, wherein both of the secondary growth semiconductor epitaxial layer and the in-situ dielectric layer are prepared through metal organic chemical vapor deposition processes applied in the same growth chamber.

18. The manufacturing method according to claim 12, wherein before preparing a semiconductor epitaxial layer above the groove, the manufacturing method further comprises:
cleaning a wafer surface to remove the gas adsorbed on the wafer surface.

19. The manufacturing method according to claim 12, wherein before preparing a semiconductor epitaxial layer above the groove, the manufacturing method further comprises:
preparing a platform formed by a mask layer through a photolithography process on the barrier layer;
wherein preparing a source electrode and a drain electrode comprises:
applying a dry etching process to remove the mask layer.

20. The manufacturing method according to claim 12, wherein after depositing a channel layer and a barrier layer above a substrate, the manufacturing method further comprises:
depositing an in-situ mask layer above the barrier layer directly in the growth chamber used for depositing the barrier layer;
wherein preparing a groove inside the barrier layer comprises:
etching the barrier layer outside the growth chamber to form a mask window.
